(19) United States
(12) Patent Application Publication
(10) Pub. No.: US 2022/0187520 A1
(43) Pub. Date: Jun. 16, 2022

(54) DISPLAY DEVICE AND METHOD OF MANUFACTURING SAME

(71) Applicant: SAMSUNG ELECTRONICS CO., LTD., Suwon-si (KR)

(72) Inventors: Sung Ki KIM, Suwon-si (KR); Hyun Jun JUNG, Suwon-si (KR)

(73) Assignee: SAMSUNG ELECTRONICS CO., LTD., Suwon-si (KR)

(21) Appl. No.: 17/688,066

(22) Filed: Mar. 7, 2022

Related U.S. Application Data
(63) Continuation of application No. PCT/KR2020/001871, filed on Feb. 11, 2020.

(30) Foreign Application Priority Data
Sep. 5, 2019 (KR) 10-2019-0110377

(51) Int. Cl. G02B 5/20; H01L 25/16; H01L 51/52; H01L 51/56; H01L 33/60; G02F 1/1335

(52) U.S. Cl. CPC G02B 5/208; H01L 25/167; H01L 51/5281; H01L 51/529; H01L 51/56; H01L 33/60; H01L 27/3244; G02F 1/133512; G02F 1/133502; G02B 5/206; H01L 2251/308; H01L 2251/5369; H01L 2933/0058; H01L 51/524

(57) ABSTRACT

A display device that reduces transfer of heat generated inside the display device, and a method of manufacturing the same. The display device comprises: a substrate that transmits electromagnetic waves emitted from inside of the display device, and a heat shielding layer including at least one of inorganic particles, metal particles, or metal nanowires that transmit electromagnetic waves in a visible band and reflect or absorb electromagnetic waves in an infrared band among the electromagnetic waves transmitted through the substrate.

### CROSS-REFERENCE TO RELATED APPLICATIONS

This application is a continuation application, under 35 U.S.C. § 111(a), of International Patent Application No. PCT/KR2020/001871, filed on Feb. 11, 2020, which claims the benefit of priority to Korean Patent Application No. 10-2019-0110377, filed on Sep. 5, 2019, in the Korean Intellectual Property Office, the disclosure of which is incorporated by reference herein in its entirety.

### BACKGROUND

### 1. Field

The present disclosure relates to a display device and a method of manufacturing the same.

### 2. Description of Related Art

In recent years, demands for display devices having high image quality together with a large area and a small thickness are increasing in addition to the function to simply display images.

Much research has been conducted to satisfy such demands, and as the results of the research, display devices having a large screen, a small thickness, and high image quality have been newly introduced into the market.

Meanwhile, a display device includes many electronic components such as a light source, and these electronic components generate heat while performing designated functions thereof. As a screen of a display device becomes larger, a heat exchange area is increased, and thus an amount of transferred radiant heat increases. Also, as a thickness of a display device decrease, an internal temperature is increased. In the case of increasing luminance of the light source to realize high image quality or using a micro-LED as a light source to realize high resolution, the internal temperature or surface temperature of the display device may increase.

### SUMMARY

In accordance with an aspect of the present disclosure, a display device includes: a substrate to transmit electromagnetic waves emitted from an inside of the display device; and a heat shielding layer including at least one of inorganic particles, metal particles, and metal nanowires to transmit electromagnetic waves in a visible band and absorb electromagnetic waves in an infrared band among the electromagnetic waves having passed through the substrate.

The heat shielding layer may be disposed above the substrate and the least one of the inorganic particles, metal particles, or metal nanowires included in the heat shielding layer may have sizes of 1 to 50 nm.

The metal particles or metal nanowires may include at least one material selected from a group comprising copper, silver, aluminum, and gold.

The inorganic particles may have sizes of 1 to 50 nm.

The inorganic particles may be are doped with an impurity to emit electromagnetic waves in a wavelength band different from the infrared band of the absorbed electromagnetic waves.

The inorganic particles may have a band gap energy corresponding to a wavelength band of infrared light generated in the display device.

The heat shielding layer may include at least one phosphor selected from Gd³⁺, —Eu³⁺, Eu²⁺, Gd³⁺, —Tb³⁺, —Er³⁺, Tb³⁺, —Yb³⁺, Tb³⁺, Tm³⁺, Pr³⁺, Nd³⁺, Ho³⁺, Dy³⁺ and Ce³⁺.

The heat shielding layer may reflect or absorb electromagnetic waves in a near infrared band or electromagnetic waves in a far infrared band.

The heat shielding layer may include a first layer including a high refractive material and a second layer including a low refractive material to prevent reflection of external light.

The display device may further include a low refractive layer and a high refractive layer disposed on the heat shielding layer to prevent reflection of external light.

The substrate may include at least one of a polarizing plate and a cover glass.

The inorganic particles may have a bandgap energy corresponding to a wavelength band of infrared light generated in the display device and are doped with an impurity to emit electromagnetic waves in a wavelength band different from the infrared band of the absorbed electromagnetic waves.

In accordance with another aspect of the present disclosure, a method of manufacturing a display device includes: forming a substrate transmitting electromagnetic waves emitted from an inside of the display device; and forming a heat shielding which includes at least one of inorganic particles, metal particles, and metal nanowires to transmit electromagnetic waves in a visible band and reflecting or absorb electromagnetic waves in an infrared band among the electromagnetic waves having passed through the substrate.

The heat shielding layer is disposed above the substrate and at least one of the inorganic particles, metal particles, or metal nanowires included in the heat shielding layer may have sizes of 1 to 50 nm.

The metal particles or metal nanowires may include at least one material selected from a group comprising copper, silver, aluminum, and gold.

the inorganic particles are doped with an impurity to emit electromagnetic waves in a wavelength band different from the infrared band of the absorbed electromagnetic waves.

The inorganic particles may have a band gap energy corresponding to a wavelength band of infrared light generated in the display device.

The heat shielding layer may include at least one phosphor selected from Gd³⁺, —Eu³⁺, Eu²⁺, Gd³⁺, —Tb³⁺, —Er³⁺, Tb³⁺, —Yb³⁺, Tb³⁺, Tm³⁺, Pr³⁺, Nd³⁺, Ho³⁺, Dy³⁺ and Ce³⁺.

The heat shielding layer may reflect or absorb electromagnetic waves in a near infrared band or electromagnetic waves in a far infrared band.

The heat shielding layer may include a first layer including a high refractive material and a second layer including a low refractive material to prevent reflection of external light.

The method may further include disposing a low refractive layer and a high refractive layer in front of the heat shielding layer.

The inorganic particles may have sizes of 1 to 50 nm.

The inorganic particles may have a band gap energy corresponding to a wavelength band of infrared light generated in the display device and the inorganic particles may be doped with an impurity to emit electromagnetic waves in a wavelength band different from the infrared band of the absorbed electromagnetic waves.

### BRIEF DESCRIPTION OF THE DRAWINGS

The above and/or other aspects of the disclosure will be more apparent by describing certain embodiments of the disclosure with reference to the accompanying drawings, in which:

FIG. 1 is a side cross-sectional view of a single pixel in the case where a display device according to an embodiment is implemented as an LCD.

FIG. 2 is a side cross-sectional view of a single pixel in the case where a display device according to an embodiment is implemented as an OLED display.

FIG. 3 is a side cross-sectional view of a single pixel in the case where a display device according to an embodiment is implemented as a micro-LED display.

FIG. 4 is a view exemplarily illustrating an appearance of a display device according to an embodiment.

FIG. 5 is a view illustrating a structure to block radiation of heat generated inside a display device according to an embodiment.

FIG. 6 is a view illustrating a heat shielding layer that reflects heat generated inside a display device according to an embodiment toward the inside.

FIG. 7 is a view illustrating a heat shielding layer that converts wavelengths of heat generated in the display device according to an embodiment.

FIG. 8 is a view illustrating energy change in an inorganic particle that absorbs an electromagnetic wave in a display device according to an embodiment.

FIG. 9 is a graph showing radiation characteristics of a display device according to an embodiment.

FIG. 10 is a graph showing transmittance characteristics of a display device according to an embodiment.

FIGS. 11 to 13 are side cross-sectional views respectively illustrating structures of a heat shielding layer and a surface-treated layer of a display device according to an embodiment.

FIGS. 14 and 15 are side cross-sectional views respectively illustrating another structure of a heat shielding layer of a display device according to an embodiment.

FIGS. 16 and 17 are side cross-sectional views of a surface-treated layer formed on a substrate of a display device according to an embodiment.

FIG. 18 is a flowchart of a method of manufacturing a display device according to an embodiment.

### DETAILED DESCRIPTION

Throughout the specification, like reference numerals refer to like elements throughout. This specification does not describe all elements of the embodiments of the present disclosure and detailed descriptions on what are well known in the art or redundant descriptions on substantially the same configurations may be omitted. The terms ‘unit, module, member, and block’ used herein may be implemented using a software or hardware component. According to an embodiment, a plurality of ‘units, modules, members, and blocks’ may also be implemented using an element and one ‘unit, module, member, and block’ may include a plurality of elements.

Throughout the specification, when an element is referred to as being “connected to” another element, it may be directly or indirectly connected to the other element and the “indirectly connected to” includes connected to the other element via a wireless communication network.

Also, it is to be understood that the terms “include” or “have” are intended to indicate the existence of elements disclosed in the specification, and are not intended to preclude the possibility that one or more other elements may exist or may be added.

Throughout the specification, it will be understood that when one element, is referred to as being “on” another element, it can be directly on the other element, or intervening elements may also be present therebetween.

Throughout the specification, when one element transmits or send a signal or data to another element, it is not intended to preclude the possibility that a third element exists between the elements and the signal or data is transmitted or sent via the third element, unless otherwise stated.

Throughout the specification, terms “first”, “second”, and the like are used to distinguish one component from another, without indicating alignment order, manufacturing order, or importance of the components.

An expression used in the singular encompasses the expression of the plural, unless otherwise indicated.

The reference numerals used in operations are used for descriptive convenience and are not intended to describe the order of operations and the operations may be performed in a different order unless the order of operations are clearly stated.

Provided are display devices for reducing transfer of heat generated inside the display devices to a user and methods of manufacturing the same.

According to the display device and the method of manufacturing the same according to an embodiment, transfer of heat generated inside the display device to a user may be reduced.

Hereinafter, a display device and a method of manufacturing the same according to an embodiment will be described with reference to the accompanying drawings.

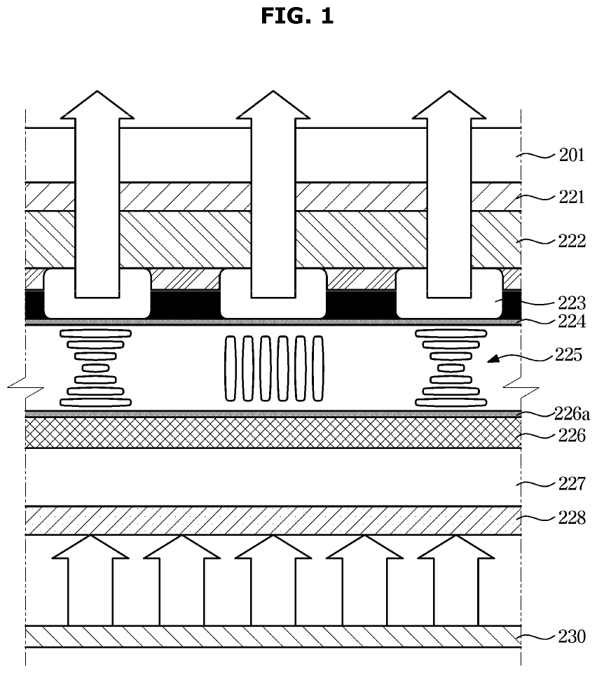

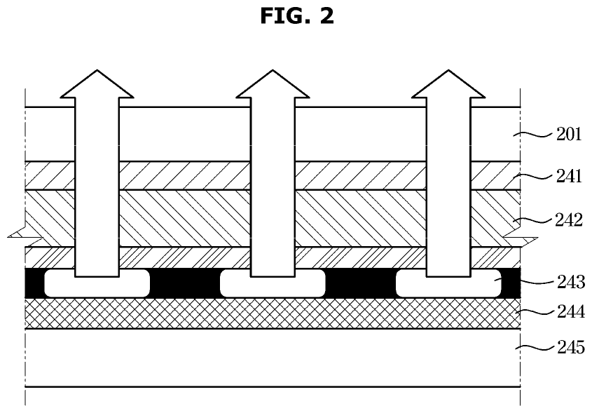

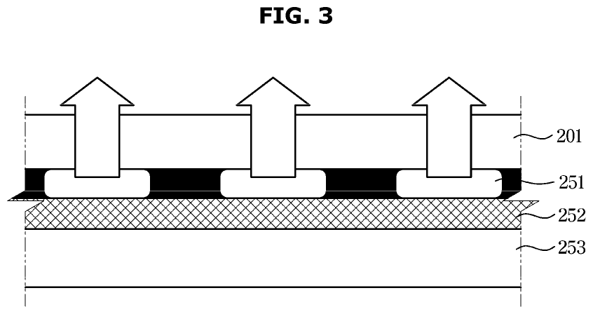

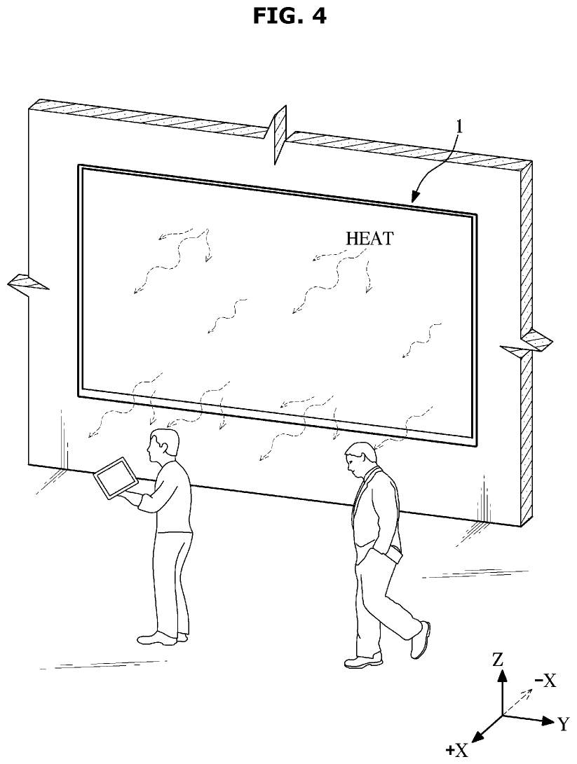

FIG. 1 is a side cross-sectional view of a single pixel in the case where a display device according to an embodiment is implemented as an LCD. FIG. 2 is a side cross-sectional view of a single pixel in the case where a display device according to an embodiment is implemented as an OLED display. FIG. 3 is a side cross-sectional view of a single pixel in the case where a display device according to an embodiment is implemented as a micro-LED display. FIG. 4 is a view exemplarily illustrating an appearance of a display device according to an embodiment.

A display device 1 according to an embodiment may employ various displaying methods using Liquid Crystal Displays (LCDs), Organic Light Emitting Diode (OLED) displays, micro-LED displays, and the like.

For example, in the case of being implemented as an LCD, the display device 1 may include a backlight 230 configured to emit surface light, a lower polarizing plate 228 vertically polarizing light emitted from the backlight 230 to transmit only light, which vibrates in the same direction as a polarization axis, to the lower substrate 227, and a TFT circuit 226 installed under the lower substrate 227 as shown in FIG. 1.

The TFT circuit 226 may be provided with a pixel electrode 226a, and a liquid crystal layer 225 may be filled between the pixel electrode 226a and a common electrode 224. In accordance with a voltage applied between the pixel electrode 226a and the common electrode 224, a current flows in the liquid crystal layer 225 and arrangement of liquid crystal molecules constituting the liquid crystal layer 225 may be adjusted when the current flows in the liquid crystal layer 225.

Light having passed through the liquid crystal layer 225 becomes to have red, green, and blue colors while passing through a color filter layer 223, and the red, green, and blue light having passed through the upper substrate 222 is horizontally polarized by an upper polarizing plate 221 and passes through a surface treatment layer and a heat shielding layer which will be described below to be emitted to the outside, thereby shown as an image by a viewer.

As another example, when the display device 1 is implemented as an OLED display as shown in FIG. 2, a TFT circuit 244 may be mounted on a lower substrate 245 and organic light emitting diodes 243 configured to emit red, green, and blue light may be disposed on the TFT circuit 244. The organic light emitting diode 243 is protected by an encapsulation layer 242, and light emitted from the organic light emitting diode 243 is polarized by the polarizing plate 241 and emitted to the outside through the surface treatment layer or the heat shielding layer which will be described below.

As another example, when the display device 1 is implemented as a micro-LED display, a TFT circuit 252 may be mounted on a lower substrate 253, and micro-LEDs 251 respectively having red, green, and blue colors are electrically connected to the TFT circuit 252 as shown in FIG. 3. Light emitted from the micro-LEDs 251 is shown by a viewer through a cover glass 201.

Regardless of the displaying method employed by the display device 1, heat is generated by a light source implemented by using a backlight, an organic material, or a plurality of micro-LEDs, and heat is also generated by various electronic components where electricity flows. In addition, when luminance is increased to enhance image quality, a considerable amount of heat is generated inside the display device 1.

Meanwhile, the display device 1 according to an embodiment may be implemented as a TV commonly used at home or a signage used in a public place for the purpose of advertisement, information delivery, product sales, and the like. When the display device 1 is implemented as a large-screen signage as shown in FIG. 4, a heat exchange area between a user and a display device 1 increases, and thus an amount of radiant energy transfer increases as well.

In order to prevent unpleasant feelings of a user caused by heat transferred from the display device 1, the display device 1 according to an embodiment has a structure to block radiation of heat generated inside to the outside. Hereinafter, the structure will be described in detail.

In the embodiment, directions defined by the coordinate system using X, Y, and Z axes are based on the display device 1. A direction (+X) where an image is output is defined as an upper side and the opposite direction (−X) is defined as a lower side. Even when the display device 1 is in a standing position as shown in FIG. 1, the direction (+X) where an image is output is defined as an upper side and the opposite direction (−X) is defined as a lower side.

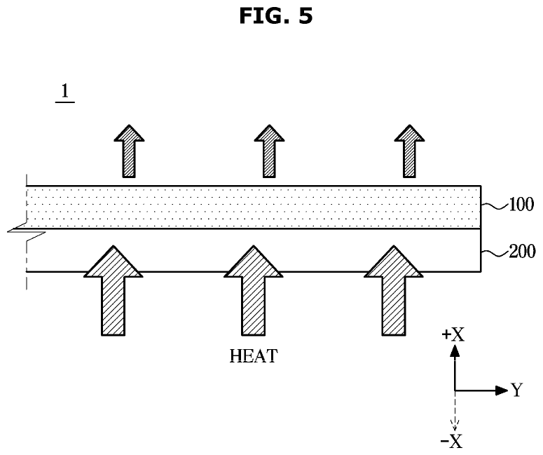

FIG. 5 is a view illustrating a structure to block radiation of heat generated inside a display device according to an embodiment.

Referring to FIG. 5, the display device 1 according to an embodiment may include a substrate 200 transmitting electromagnetic waves, such as visible light and infrared light, generated inside the display device 1, and a heat shielding layer 100 disposed above the substrate 200 and reducing radiant heat emitted to the outside by transmitting electromagnetic waves in the visible band and blocking electromagnetic waves in the infrared band among electromagnetic waves generated inside the display device 1.

Electromagnetic waves may be classified into ultraviolet light, visible light, and infrared light, etc., according to wavelength thereof. Visible light has a wavelength of about 380 to 750 nm, and infrared light has a wavelength of about 0.75 to 1000 μm. In general, light having a wavelength of 0.75 to 3 μm is referred to as near infrared light, light having a wavelength of 3 to 6 μm is referred to as middle infrared light, and light having a wavelength of 6 to 15 μm is referred to as far infrared light. Light having a wavelength of 15 to 1000 μm is referred to as extreme infrared light.

Heat generated in the display device 1 corresponds to electromagnetic waves in the infrared band, and electromagnetic waves in the visible band are generated to realize an image. Therefore, the heat shielding layer 100 transmits visible light to emit the visible light the outside and blocks infrared light to prevent or minimize radiation of the infrared light to the outside.

The substrate 200 may be disposed above the light emitting devices such as the backlight 230, the organic material 243, or the micro-LED 251 and components serving as heat-generating elements such as various electronic components.

Therefore, the substrate 200 may have a structure or a material capable of transmitting electromagnetic waves emitted from a position therebelow. For example, when the display device 1 is implemented as an LCD or OLED display, the substrate 200 may be the upper polarizing plate 221 (See FIG. 1) or the polarizing plate 241 (See FIG. 2). In this case, the heat shielding layer 100 may be disposed on the upper polarizing plate 221 or the polarizing plate 241.

In addition, when the display device 1 is implemented as a micro-LED display, the substrate 200 may be a cover glass 201. Therefore, the heat shielding layer 1 may be disposed on the cover glass 201.

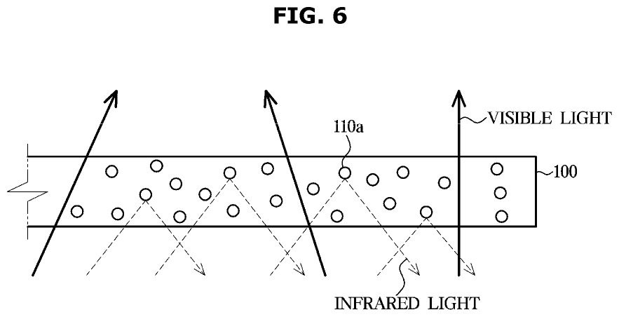

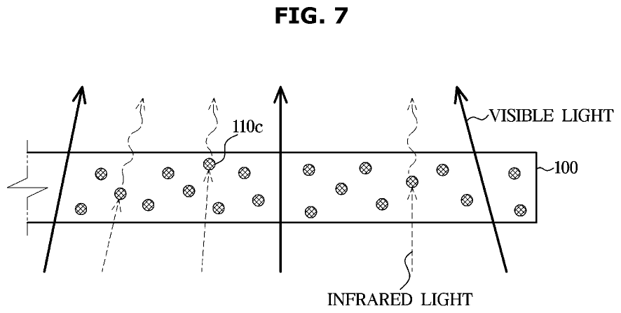

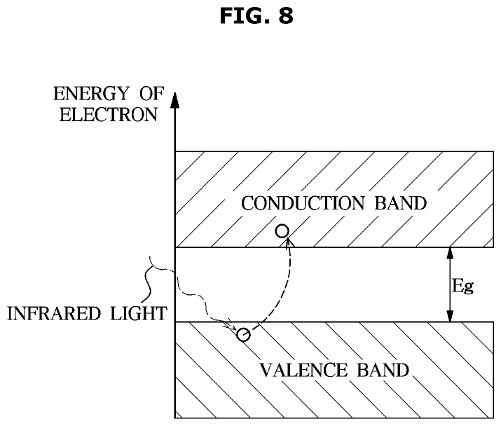

FIG. 6 is a view illustrating a heat shielding layer that reflects heat generated inside a display device according to an embodiment toward the inside. FIG. 7 is a view illustrating a heat shielding layer that converts wavelengths of heat generated in the display device according to an embodiment. FIG. 8 is a view illustrating energy change in an inorganic particle that absorbs an electromagnetic wave in a display device according to an embodiment.

For example, as shown in FIG. 6, the heat shielding layer 100 may include nano-sized metal particles 110a or metal nanowires. The metal particles 110a or metal nanowires may be selected from metals including copper, silver, aluminum, and gold and the size thereof may be selected from a range of 1 to 50 nm. As described above, by using the nano-sized metal particles 110a and metal nanowires, the heat shielding layer 100 may have transparency and output of an image may not be affected thereby. Therefore, the size of the metal particles 110a or metal nanowires may be appropriately selected in consideration of transparency and blocking performance.

For example, the heat shielding layer 100 may include silver nanopowder or copper nanopowder. A material of the metal nanowires may also be selected from metals including copper, silver, aluminum, and gold. For example, the heat shielding layer 100 may include silver nanowires or copper-silver nanowires.

The metal particles 110a including free electrons may be regarded as being in a solid plasma state in which free electrons freely move forming an electric filed to return the density of free electrons to a uniform state. Inertia is generated in the motion of electrons by the electric field causing plasma oscillation, and electromagnetic waves having a smaller frequency than that of plasma oscillation, i.e., in a long wavelength region (infrared light region), cannot pass through the heat shielding layer 100 but are reflected by the metal particles 110a and absorbed back by the inside of the display device 1.

On the contrary, visible light used to realize an image corresponds to electromagnetic waves having a greater frequency than that of plasma oscillation, and thus visible light is not reflected by the metal particles 110a but passes through the heat shielding layer 100, thereby being emitted to the outside.

Meanwhile, it is possible to selectively block infrared light in a particular wavelength band. For example, it is possible to block near infrared light or far infrared light which considerably affects the human body. The wavelength band to be blocked may vary according to types of materials constituting the metal particles 110a or metal nanowires. Therefore, infrared light in a desired wavelength band may be blocked by appropriately designing the type of a material constituting the metal particles 110a or metal nanowires.

As another example, as shown in FIG. 7, the heat shielding layer 100 may include nano-sized inorganic particles 110c. For example, the inorganic particles 110c may be particles of an inorganic oxide such as CeWO, indium tin oxide (ITO), and antimony tin oxide (ATO) and the size thereof may be selected from a range of 1 to 50 nm.

Referring to FIG. 8, when electromagnetic waves having an energy corresponding to a band gap are incident on the inorganic particles 110c, the inorganic particles 110c absorb the electromagnetic waves and electrons in a valence band are excited to a conduction band. An inorganic oxide such as ITO and ATO has both excellent ability to absorb electromagnetic waves in the infrared band and excellent ability to transmit electromagnetic waves in the visible band.

Specifically, the inorganic particles 110c absorb electromagnetic waves having an energy identical or similar to a band gap the most. Because band gap characteristics vary according to materials, the type of the inorganic particles 110c may be selected in consideration of energy bands of electromagnetic waves to be blocked.

That is, the inorganic particles 110c may have a bandgap energy determined according to the wavelength band of electromagnetic waves mainly generated in the display device 1.

Meanwhile, while the excited electrons fall to the valence band, electromagnetic waves having a wavelength similar to that of absorbed electromagnetic waves are emitted. By increasing free electrons in the inorganic particles 110c, the display device 1 according to an embodiment may emit electromagnetic waves in a wavelength band different from that of absorbed electromagnetic waves as shown in FIG. 7. In this case, heat radiated out of the display device 1 may be blocked by emitting electromagnetic waves having a wavelength band that does not thermally affect the human body. For example, free electrons may be increased by doping the inorganic particles 110c with an impurity such as palladium (Pd) or titanium (Ti) or by increasing electrical conductivity of the inorganic particles 110c.

For example, when the inorganic particles 110c are designed to absorb electromagnetic waves in the near infrared band, the inorganic particles 110c may be doped with an impurity to re-emit electromagnetic waves in the middle infrared light band. When the inorganic particles 110c are designed to absorb electromagnetic waves in the far infrared band, the inorganic particles 110c may be doped with an impurity to re-emit longer electromagnetic waves in the extreme infrared band.

The type of the impurity doped thereon may be determined according to the wavelength band of electromagnetic waves to be re-emitted.

In addition, for efficient wavelength conversion of the re-emitted electromagnetic waves, a phosphor, as a wavelength-converting material, may be doped on the inorganic particles 110c. For example, a downconverting phosphor used as a wavelength-converting material such as Gd³⁺, —Eu³⁺, Eu²⁺, Gd³⁺, —Tb³⁺, —Er³⁺, Tb³⁺, —Yb³⁺, Tb³⁺, Tm³⁺, Pr³⁺, Nd³⁺, Ho³⁺, Dy³⁺, or Ce³⁺ may be doped. Alternatively, an upconverting phosphor performing conversion into a wavelength in a higher energy band may also be doped thereon to convert electromagnetic waves in the far infrared band into electromagnetic waves in the middle infrared light.

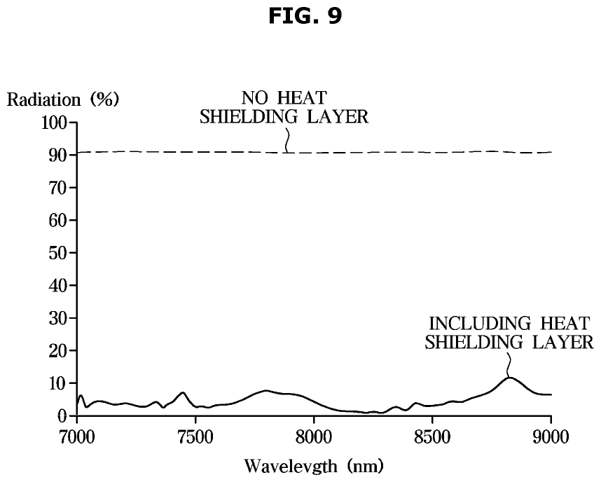

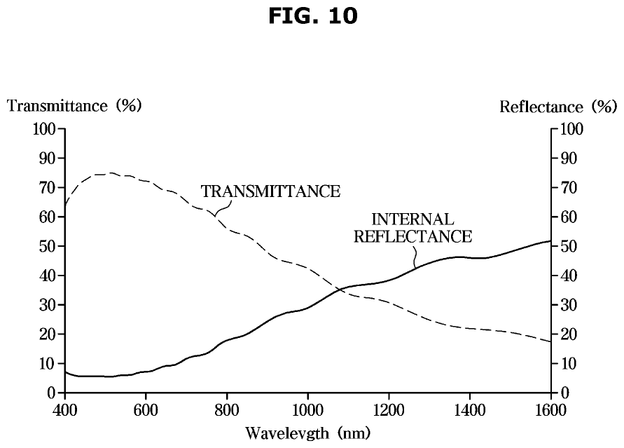

FIG. 9 is a graph showing radiation characteristics of a display device according to an embodiment FIG. 10 is a graph showing transmittance characteristics of a display device according to an embodiment.

Referring to FIG. 9, it may be confirmed that in a display device not including the heat shielding layer 100, most of infrared light in the wavelength range of 7000 to 9000 nm generated inside the display device is radiated to the outside. It may also be confirmed that in the display device 1 including the heat shielding layer 100, most of infrared light in the wavelength range of 7000 to 9000 nm generated inside the display device 1 is blocked without being radiated to the outside.

Also, referring to FIG. 10, it may be confirmed that electromagnetic waves in the visible band generated inside the display device 1 exhibit excellent transmittance and electromagnetic waves in the near infrared band exhibit excellent internal reflectance.

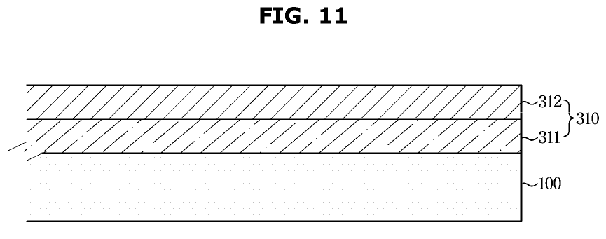

FIGS. 11 to 13 are side cross-sectional views respectively illustrating structures of a heat shielding layer and a surface-treated layer of a display device according to an embodiment.

Because the substrate 200 is located at the upper side of the display device 1 where an image is output, various surface-treated layers performing various functions may be located on the substrate 200 in addition to the heat shielding layer 100.

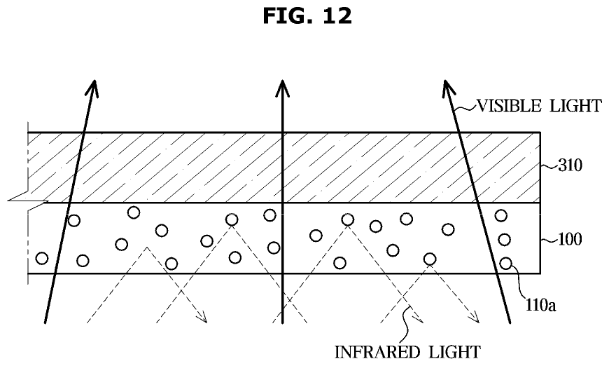

For example, as shown in FIGS. 11 and 12, an anti-reflection layer 310 to prevent reflection of external light may be located on the heat shielding layer 100. The anti-reflection layer 310 may prevent image distortion caused by reflection of external light incident from the outside of the display device 1.

Also, the anti-reflection layer 310 may reduce Fresnel reflection, in which light heading toward the outside after having passed through the substrate 200 is partially reflected by an interface of the substrate 200 and returns to the inside of the display device 1, and may increase transmittance, thereby increasing light emission efficiency.

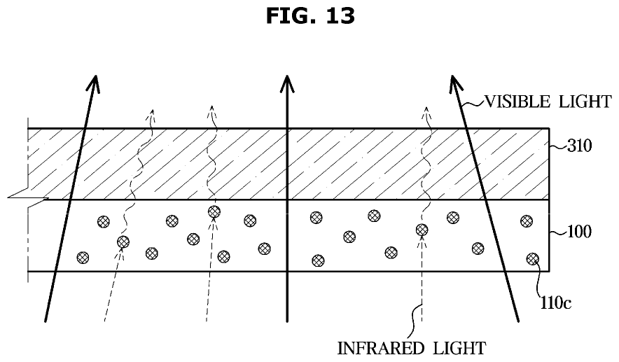

For example, as shown in FIG. 13, the anti-reflection layer 310 may include a high refractive layer 311 including a material having a high refractive index and a low refractive layer 312 including a material having a low refractive index to offset external light using destructive interface of light reflected by the surface. The order of the high refractive layer 311 and the low refractive layer 312 may be altered and these layers may be arranged in plural to cross each other.

As the material having a low refractive index, a low refractive oxide such as silicon dioxide (SiO₂) may be employed. As the material having a high refractive index, a high refractive oxide such as titanium dioxide (TiO₂), zirconium dioxide (ZrO₂), lithium niobate (LiNbO₃), lithium tantalate (LiTaO₃), and lanthanum titanium (LaTiO₂) may be employed.

For example, the high refractive layer 311 may have a refractive index of 1.70 to 2.80 or 1.90 to 2.80 and the low refractive layer 312 may have a refractive index of 1.20 to 1.50.

Meanwhile, when the high refractive layer 311 or the low refractive layer 312 may have a thickness of 50 μm or less in the case of including an inorganic material and may have a thickness of 200 nm or less in the case of including an organic material.

Alternatively, the anti-reflection layer 310 may also include a low reflection film causing diffused reflection at the surface.

In addition, an anti-glare layer capable of inhibiting glare caused by diffuse reflection of external light via anti-glare treatment using surface irregularities may be disposed on the heat shielding layer 100 or both an anti-reflection layer and an anti-glare layer may be disposed thereon.

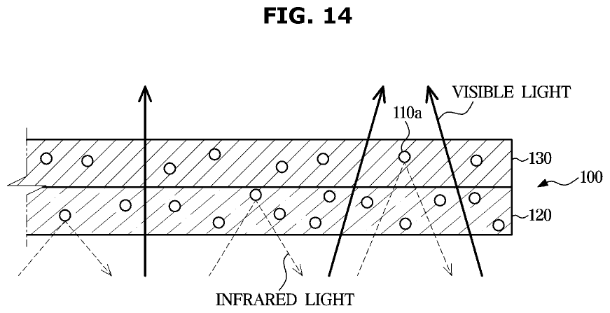

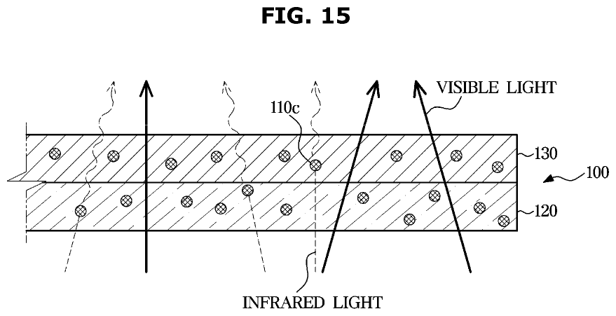

FIGS. 14 and 15 are side cross-sectional views respectively illustrating another structure of a heat shielding layer of a display device according to an embodiment.

In the example previously described above, a case in which the anti-reflection layer 310 is located on the heat shielding layer 100 is described. As another example, as shown in FIGS. 14 and 15, the heat shielding layer 100 may also include an anti-reflection material.

The heat shielding layer 100 including the metal particles 110a, the metal nanowires, or the inorganic oxide 110c is divided into a first layer 120 and a second layer 130, and the first layer 120 may include one of a high refractive material and a low refractive material and the second layer 130 may include the other. In addition, a plurality of the first layers 120 and the second layers 120 may be arranged to cross each other.

The heat shielding layer 100 having the structure as described above may block radiation of heat generated inside the display device 1 to the outside simultaneously blocking reflection of external light.

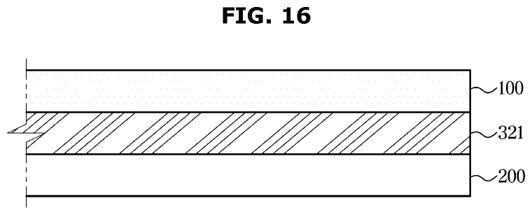

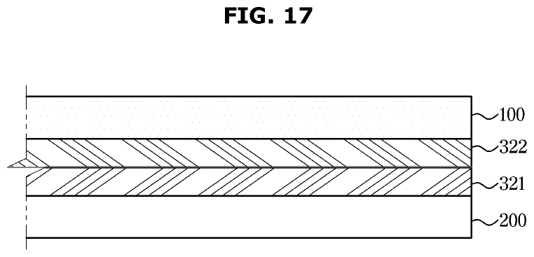

FIGS. 16 and 17 are side cross-sectional views of a surface-treated layer formed on a substrate of a display device according to an embodiment.

As shown in FIG. 16, a base layer 321 may be disposed on a substrate 200 and a heat shielding layer 100 may be disposed on the base layer 321.

A material constituting the base layer 321 may vary according to the type of the substrate 200. For example, when the substrate 200 is a polarizing plate, the base layer 321 may include a tri-acetyl cellulose (TAC) film, a polyethylene terephthalate (PET) film, an acrylic film, or a cyclo-olefin polymer (COP) film to protect polyvinyl alcohol (PVA) that realizes a key function of the polarizing plate.

Also, as shown in FIG. 17, a hard coating layer 322 may further be disposed between the heat shielding layer 100 and the base layer 321 to maintain surface hardness.

Hereinafter, an example of a method of manufacturing the display apparatus 1 will be described.

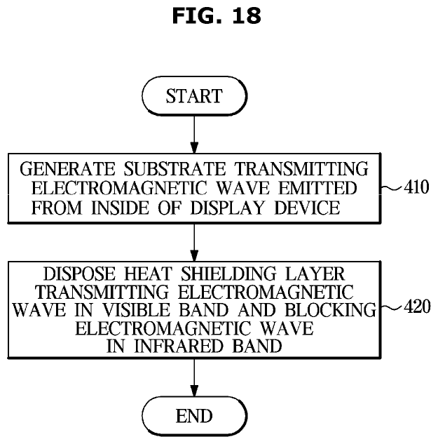

FIG. 18 is a flowchart of a method of manufacturing a display device according to an embodiment.

Referring to FIG. 18, the method of manufacturing a display device according to an embodiment may include generating a substrate that transmits electromagnetic waves emitted from the inside of the display device (410), and disposing a heat shielding layer on the substrate, the heat shielding layer reducing radiant heat heading toward the outside by transmitting electromagnetic waves in the visible band and blocking electromagnetic waves in the infrared band among the electromagnetic waves having passed through the substrate (420).

The heat shielding layer may include at least one of inorganic particles, metal particles, and metal nanowires which reflect or absorb the electromagnetic waves in the infrared band.

As described above, the substrate 200 may have a structure or a material capable of transmitting electromagnetic waves and may be disposed above light emitting devices such as the backlight 230, the organic material 243, and the micro-LED 251 or components serving as heat-generating elements such as various electronic components.

For example, when the display device 1 is implemented as an LCD or an OLED display, the substrate 200 may be the upper polarizing plate 221 (See FIG. 1) or the polarizing plate 241 (See FIG. 2).

The heat shielding layer 100 may be disposed on the upper polarizing plate 221 or the polarizing plate 241. Alternatively, the substrate 200 may also be the cover glass 201.

In addition, when the display device 1 is implemented as a micro-LED display, the substrate 200 may be the cover glass 201. Therefore, the heat shielding layer 1 may be disposed on the cover glass 201.

Disposing the heat shielding layer 100 above the substrate 200 may include coating the heat shielding layer 100 on the surface of the substrate 200 or on the surface-treated layer formed on the surface of the substrate 200 by any method selected between wet coating or dry coating in accordance with a material constituting the heat shielding layer 100. In the case of using dry coating, sputtering, thermal evaporation, E-beam evaporation, or the like may be applied thereto.

The heat shielding layer 100 may include metal particles or metal nanowires selected from the group consisting of copper, silver, aluminum, and gold which reflect electromagnetic waves in the infrared band. For example, the heat shielding layer 100 may be in a form in which nano-sized metal particles are dispersed in a dispersion solvent or a matrix. In this case, the size of the metal nanowires or metal particles may be selected from a range of 1 to 50 nm.

Alternatively, the heat shielding layer 100 may also include inorganic particles that absorb electromagnetic waves in the infrared band. In this regard, the inorganic particles may be particles of an inorganic oxide. The particles of the inorganic oxide may be selected form materials such as CeWO, ITO, and ATO and may have a nano-size selected from a range of 1 to 50 nm.

Meanwhile, the particles of the inorganic oxide of the heat shielding layer 100 may absorb electromagnetic waves having an energy corresponding to a band gap energy. Therefore, the type of the inorganic oxide may be selected in consideration of a wavelength band of electromagnetic waves to be absorbed, i.e., a wavelength band of infrared light mainly emitted from the display device 1.

When the particles of the inorganic oxide absorbs electromagnetic waves having an energy corresponding to the band gap energy, electrons of the valence band are excited into the conduction band and emit electromagnetic waves while falling back to the valence band. In this case, the inorganic oxide may be doped with an impurity such as palladium (Pd) and titanium (Ti) to emit electromagnetic waves in a wavelength band different from that of the absorbed electromagnetic waves, i.e., a wavelength band not thermally affecting the human body.

Alternatively, the inorganic oxide may be doped with a phosphor used as a wavelength-converting material to increase wavelength conversion efficiency. For example, a downconverting phosphor such as Gd³⁺, —Eu³⁺, Eu²⁺, Gd³⁺, —Tb³⁺, —Er³⁺, Tb³⁺, —Yb³⁺, Tb³⁺, Tm³⁺, Pr³⁺, Nd³⁺, Ho³⁺, Dy³⁺, and Ce³⁺ may be used for the doping.

In addition, the low refractive layer 312 and the high refractive layer 311 may be disposed on the heat shielding layer 100 to prevent reflection of external light, and the heat shielding layer 100 may also include the first layer 120 including a high refractive material and the second layer 130 including a low refractive material. In this regard, the low refractive layer 312 and the high refractive layer 311 are as described above.

In addition, the base layer 321 may be disposed under the heat shielding layer 100 and on the substrate 200, and the heat shielding layer 100 may be disposed on the base layer 321.

A material constituting the base layer 321 may vary according to the type of the substrate 200. For example, when the substrate 200 is a polarizing plate, the base layer 321 may include a tri-acetyl cellulose (TAC) film, a polyethylene terephthalate (PET) film, an acrylic film, or a cyclo-olefin polymer (COP) film.

Also, a hard coating layer 322 may further be disposed between the heat shielding layer 100 and the base layer 321 to maintain surface hardness.

The disposing of the layers may include coating the layers by wet coating or dry coating in the embodiment.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A display device comprising:
a substrate to transmit electromagnetic waves emitted from inside of the display device; and
a heat shielding layer disposed above the substrate and including at least one of inorganic particles, metal particles, and metal nanowires to transmit electromagnetic waves in a visible band and absorb electromagnetic waves in an infrared band among the electromagnetic waves having passed through the substrate.

2. The display device according to claim 1, wherein the at least one of inorganic particles, metal particles, or metal nanowires included in the heat shielding layer have sizes of 1 to 50 nm.

3. The display device according to claim 1, wherein the metal particles or the metal nanowires comprise at least one material selected from a group comprising copper, silver, aluminum, and gold.

4. The display device according to claim 1, wherein the inorganic particles have sizes of 1 to 50 nm.

5. The display device according to claim 1, wherein the inorganic particles are doped with an impurity to emit electromagnetic waves in a wavelength band different from the infrared band of the absorbed electromagnetic waves.

6. The display device according to claim 1, wherein the inorganic particles have a band gap energy corresponding to a wavelength band of infrared light generated in the display device.

7. The display device according to claim 5, wherein the heat shielding layer comprises at least one phosphor selected from Gd³⁺, —Eu³⁺, Eu²⁺, Gd³⁺, —Tb³⁺, —Er³⁺, Tb³⁺, —Yb³⁺, Tb³⁺, Tm³⁺, Pr³⁺, Nd³⁺, Ho³⁺, Dy³⁺ and Ce³⁺.

8. The display device according to claim 1, wherein the heat shielding layer reflects or absorbs electromagnetic waves in a near infrared band or electromagnetic waves in a far infrared band.

9. The display device according to claim 1, wherein the heat shielding layer comprises a first layer including a high refractive material and a second layer including a low refractive material to prevent reflection of external light.

10. The display device according to claim 1, further comprising a low refractive layer and a high refractive layer disposed on the heat shielding layer to prevent reflection of external light.

11. The display device according to claim 1, wherein the substrate comprises at least one of a polarizing plate and a cover glass.

12. The display device according to claim 1, wherein the inorganic particles have a bandgap energy corresponding to a wavelength band of infrared light generated in the display device and are doped with an impurity to emit electromagnetic waves in a wavelength band different from the infrared band of the absorbed electromagnetic waves.

13. A method of manufacturing a display device, the method comprising:
forming a substrate to transmit electromagnetic waves emitted from an inside of the display device; and
forming a heat shielding layer above the substrate, the heat shielding layer including at least one of inorganic particles, metal particles, and metal nanowires to transmit electromagnetic waves in a visible band and reflecting or absorb electromagnetic waves in an infrared band among the electromagnetic waves having passed through the substrate.

14. The method according to claim 13, wherein at least one of the inorganic particles are doped with an impurity to emit electromagnetic waves in a wavelength band different from the infrared band of the absorbed electromagnetic waves.

15. The method according to claim 13, wherein the inorganic particles have a band gap energy corresponding to a wavelength band of infrared light generated in the display device.
